(19) United States
(12) Patent Application Publication
(10) Pub. No.: US 2026/0227430 A1
(43) Pub. Date: Aug. 6, 2026

(54) CURRENT SENSE CIRCUITRY

(71) Applicant: TEXAS INSTRUMENTS INCORPORATED, Dallas, TX (US)

(72) Inventors: Anil Srikanth DOWLESWARAPU, Hyderabad (IN); Venkata Naresh KOTIKELAPUDI, Bengaluru (IN); Abhishek GUPTA, Begnaluru (IN)

(21) Appl. No.: 19/042,185

(22) Filed: Jan. 31, 2025

(51) Int. Cl. G01R 19/22; H03F 3/04; H03K 3/017

(52) U.S. Cl. CPC G01R 19/22; H03F 3/04; H03K 3/017; H03F 2200/462

(57) ABSTRACT

Current sense circuitry includes: a first amplifier; a transistor; and a second amplifier. The first amplifier has a first terminal, a second terminal, and a third terminal. The transistor has a first terminal, a second terminal, and a control terminal. The first terminal of the transistor is coupled to the third terminal of the first amplifier. The second amplifier has a first terminal, a second terminal, and a third terminal. The first terminal of the second amplifier is coupled to the second terminal of the transistor.

### BACKGROUND

Many electrical systems rely on current sensing as part of a control loop. In some scenarios, a control loop benefits from bi-directional current sensing. Some existing bi-directional current sensing options are costly, complex, or inaccurate.

### SUMMARY

In an example, current sense circuitry includes: a first amplifier having a first terminal, a second terminal, and a third terminal; a transistor having first terminal, a second terminal, and a control terminal, the first terminal of the transistor coupled to the third terminal of the first amplifier; and a second amplifier having a first terminal, a second terminal, and a third terminal. The first terminal of the second amplifier is coupled to the second terminal of the transistor.

In another example, a circuit includes: a first transistor; a first amplifier; a first resistor; a second resistor; a third resistor; a fourth resistor; a second transistor; and a second amplifier. The first transistor has a first terminal, a second terminal, and a control terminal. The first amplifier has a first terminal, a second terminal, and a third terminal. The first terminal of the first amplifier coupled to the first terminal of the first transistor. The first resistor has a first terminal and a second terminal. The first terminal of the first resistor is coupled to the first terminal of the first amplifier. The second resistor has a first terminal and a second terminal. The first terminal of the second resistor is coupled to the first terminal of the first amplifier. The second terminal of the second resistor is coupled to the third terminal of the first amplifier. The third resistor has a first terminal and a second terminal. The second terminal of the third resistor is coupled to the second terminal of the first amplifier. The fourth resistor has a first terminal and a second terminal. The first terminal of the fourth resistor is coupled to the second terminal of the first amplifier. The second transistor has a first terminal, a second terminal, and a control terminal. The first terminal of the second transistor is coupled to the third terminal of the first amplifier. The second amplifier has a first terminal, a second terminal, and a third terminal. The first terminal of the second amplifier is coupled to the second terminal of the second transistor.

In yet another example, a circuit includes: a transistor; first amplifier circuitry; second amplifier circuitry; third amplifier circuitry; and control circuitry. The transistor has a first terminal, a second terminal, and a control terminal. The first amplifier circuitry has a first terminal, a second terminal, and a third terminal. The third terminal of the first amplifier circuitry is coupled to the first terminal of the transistor. The second amplifier circuitry has a first terminal, a second terminal, and a third terminal. The first terminal of the second amplifier circuitry is coupled to the second terminal of the transistor. The third amplifier circuitry has a first terminal, a second terminal, a third terminal, and a fourth terminal. The first terminal of the third amplifier circuitry is coupled to the third terminal of the second amplifier circuitry. The control circuitry has a terminal coupled to the fourth terminal of the third amplifier circuitry.

### BRIEF DESCRIPTION OF THE DRAWINGS

FIG. 1 is a diagram showing an example system.

FIG. 2 is a diagram showing example current sense circuitry.

FIG. 3 is a diagram showing other example current sense circuitry.

FIG. 4 is a graph showing example current sense results.

FIG. 5 is a diagram showing other example current sense circuitry.

FIG. 6 is a flowchart showing example calibration of current sense circuitry.

FIG. 7 is a schematic diagram showing example level-shift circuitry.

FIG. 8 is a diagram showing example gain control circuitry.

FIG. 9 is a timing diagram showing example gain control circuitry signals.

FIG. 10 is a graph showing example current and current sense results.

### DETAILED DESCRIPTION

The same reference numbers or other reference designators are used in the drawings to designate the same or similar features. Such features may be the same or similar either by function and/or structure.

In some examples, current sense circuitry includes a single sense transistor (e.g., a field-effect transistor or “FET”) and does not need current direction information. The sense transistor has a first terminal, a second terminal, and a control terminal. By avoiding current direction information, gain trim time and complexity is reduced (e.g., dynamic switching between gain trims between positive and negative current is avoided). To avoid current direction information, the common mode of the sense transistor (i.e., the voltage at the first terminal, the second terminal, and the control terminal of the sense transistor) is based on a target common mode voltage (Vmid herein) so that final current results are linearized around Vmid.

In some examples, the current sense circuitry includes: first voltage control circuitry; second voltage control circuitry; and switch control circuitry. The first voltage control circuitry sets the voltage at the first terminal of the sense transistor to a first voltage plus Vmid. The first voltage control circuitry sets the voltage at the second terminal of the sense transistor to Vmid. The switch control circuitry sets the voltage at the control terminal of the sense transistor to Vmid plus a switch control signal. In some examples, each of the first voltage control circuitry and the second voltage control circuitry is a push-pull class AB amplifier. In some examples, driving FETs of the first voltage control circuitry and the second voltage control circuitry carry bias current even when there is no current to be sensed, which eliminates distortion when the sense current is near zero (e.g., when the sense current has a zero-crossing from positive to negative or vice versa).

In some examples, the current sense circuitry includes trimmable components, which avoids external trimming operations and reduces overall test time. In some examples, the current sense circuitry includes a first trimmable resistor bank (e.g., resistor R6 herein) for gain selection and a second trimmable resistor bank (e.g., resistor R7 herein) for gain trim, which provides a compact layout for the first trimmable resistor bank and provides better resistor matching across gain configuration options.

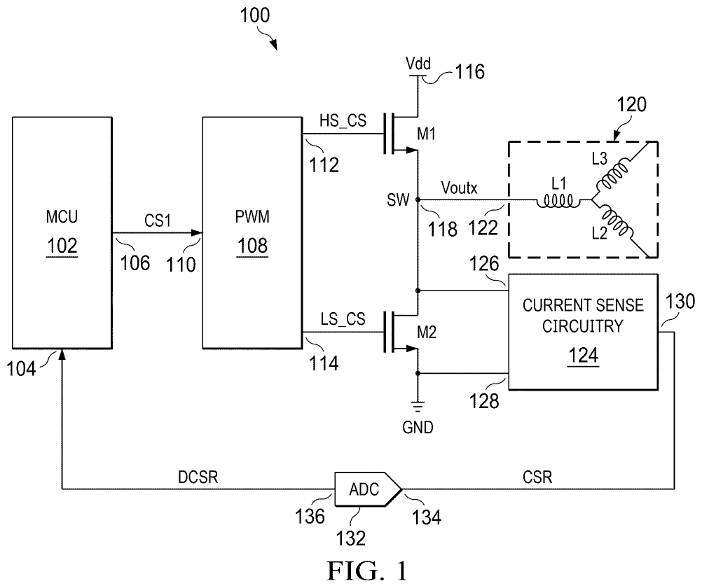

FIG. 1 is a diagram showing an example system 100. As shown, the system 100 includes a power supply (Vdd) terminal 116, a microcontroller (MCU) 102, a pulse-width modulator (PWM) 108, transistors M1 and M2, a switch node 118 (also referred to as a switching terminal or an output terminal) between the transistors M1 and M2, a motor 120 with inductors L1 to L3, current sense circuitry 124, and an analog-to-digital converter (ADC) 132. The MCU 102 has a first terminal 104 and a second terminal 106. The PWM 108 has a first terminal 110, a second terminal 112, and a third terminal 114. In the example of FIG. 1, the transistors M1 and M2 are n-channel metal-oxide semiconductor (NMOS) transistor. Each of the transistors M1 and M2 has a respective first terminal, a second terminal, and a control terminal. The motor 120 a terminal 122. In the example of FIG. 1, the terminal 122 is coupled to the inductor L1 for current sensing of the current through the inductor L1. The current sense circuitry 124 has a first terminal 126, a second terminal 128, and a third terminal 130. The ADC 132 has a first terminal 134 and a second terminal 136.

In the example of FIG. 1, the second terminal 106 of the MCU 102 is coupled to the first terminal 110 of the PWM 108. The second terminal 112 of the PWM 108 is coupled to the control terminal of the transistor M1. The first terminal of the transistor M1 is coupled to the Vdd terminal 116. The second terminal of the transistor M1 is coupled to the inductor L1, the first terminal of the transistor M2 and the first terminal 126 of the current sense circuitry 124. The second terminal of the transistor M2 is coupled to the second terminal 128 of the current sense circuitry 124 and to ground or a ground terminal. The third terminal 130 of the current sense circuitry 124 is coupled to the first terminal 134 of the ADC 132. The second terminal 136 of the ADC 132 is coupled to the first terminal 104 of the MCU.

The MCU 102 operates to: receive digitized current sense results (DCSR) at the first terminal 104; and provide a control signal CS1 at the second terminal 106 responsive to the digitized current sense results. The PWM 108 operates to: receive CS1 at the first terminal 110; provide a high-side control signal (HS_CS) at the second terminal 112 responsive to CS1; and provide a low-side control signal (LS_CS) at the third terminal 114 responsive to CS1. The transistor M1 is turned on/off responsive to HS_CS (e.g., HS_CS high results in M1 on, and HS_CS low results in M1 off). The transistor M2 is turned on/off responsive to LS_CS (e.g., LS_CS high results in M2 on, and HS_CS low results in M2 off). The current at the switch node 118 is a function of the on/off states of M1 and M2, and operations of the motor 120. The voltage at the switch node 118 is Voutx. In some examples, the current sense circuitry 124 operates to: receive Voutx at the first terminal 126; receive a ground voltage at the second terminal 128; and provide current sense results (CSR) at the third terminal 130 responsive to the difference between Voutx and ground. The ADC 132 operates to: receive CSR at the first terminal 134; and provide DCSR at the second terminal 136 responsive to CSR.

In the example of FIG. 1, the system 100 provides a motor control loop responsive to current sensing for the inductor L1 of the motor 120. In some examples, the system 100 includes an additional PWM (not shown), additional transistors (not shown), an additional current sense circuitry (not shown), and an additional ADC (not shown) for each of the inductors L2 and L3 of the motor 120. In such examples, the MCU 102 receives digitized current sense results for the inductors L1 to L3 of the motor 120 and adjust control signals as needed (e.g., to adjust motor speed or position).

In some examples, the motor 120 of the system 100 may be replaced by an audio system, or other controlled electronics. In such examples, the control loop uses current sensing for audio power control or other controlled parameters.

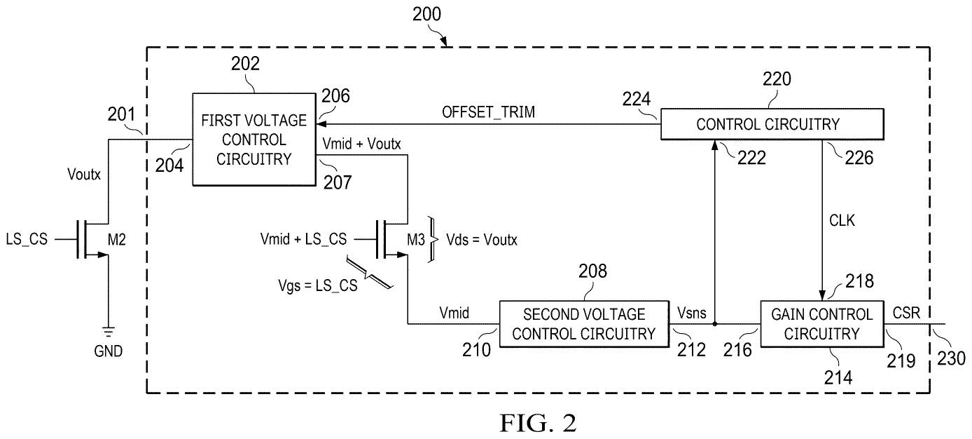

FIG. 2 is a diagram showing example current sense circuitry 200 and the transistor M2. The current sense circuitry 200 is an example of the current sense circuitry 124 in FIG. 1. The current sense circuitry 200 has a first terminal 201 and a second terminal 230. The first terminal 201 of the current sense circuitry 200 is an example of the first terminal 126 of the current sense circuitry 124 in FIG. 1. The second terminal 230 of the current sense circuitry 200 is an example of the third terminal 130 of the current sense circuitry 124 in FIG. 1. In the example of FIG. 2, current sense circuitry 200 includes first voltage control circuitry 202, a transistor M3, second voltage control circuitry 208, gain control circuitry 214, and control circuitry 220. In some examples, each of the first voltage control circuitry 202 and the second voltage control circuitry is a push-pull class AB amplifier. The first voltage control circuitry 202 has a first terminal 204, a second terminal 206, and a third terminal 207. The transistor M3 has a first terminal, a second terminal, and a control terminal. The second voltage control circuitry 208 has a first terminal 210 and a second terminal 212. The gain control circuitry 214 has a first terminal 216, a second terminal 218, and a third terminal 219. The control circuitry 220 has a first terminal 222, a second terminal 224, and a third terminal 226.

In the example of FIG. 2, the first terminal 201 of the current sense circuitry is coupled to the first terminal of the transistor M2 and the first terminal 204 of the first voltage control circuitry 202. The second terminal 206 of the first voltage control circuitry 202 is coupled to the second terminal of the control circuitry 220. The third terminal 207 of the first voltage control circuitry 202 is coupled to the first terminal of the transistor M3. The second terminal of the transistor M3 is coupled to the first terminal 210 of the second voltage control circuitry 208. The second terminal 212 of the second voltage control circuitry 208 is coupled to the first terminal 222 of the control circuitry 220 and the first terminal 216 of the gain control circuitry 214. The second terminal 218 of the gain control circuitry 214 is coupled to the third terminal 226 of the control circuitry 220. The third terminal 219 of the gain control circuitry 214 is coupled to the second terminal 230 of the current sense circuitry 200.

In the example of FIG. 2, Voutx at the first terminal of the transistor M2 is based on the operations of a control loop as in FIG. 1. The control terminal of the transistor M2 receives LS_CS. The control circuitry 220 operates to: receive the sense voltage Vsns at the first terminal 222; provide a trim control signal (OFFSET_TRIM) at the second terminal 224 responsive to Vsns; and provide a clock signal (CLK) at the third terminal 226. The first voltage control circuitry 202 operates to: receive Voutx at the first terminal 204; receive a trim control signal (OFFSET_TRIM) at the second terminal 206; and provide a voltage level Vmid+Voutx at the third terminal 207 responsive to Voutx and OFFSET_TRIM, where Vmid is a target common mode voltage (midpoint) for the sense results. The first terminal of the transistor M3 is thus set at Vmid+Voutx. The control terminal of the transistor M3 receives Vmid+LS_CS. In some examples, LS_CS=the gate-to-source voltage (Vgs) of the transistor M3, and Vmid is the common mode voltage greater than zero. The second terminal of the transistor M3 is set at Vmid based on the operations of the second voltage control circuitry 208. In some examples, the drain-to-source voltage (Vds) of the transistor M3 is Voutx. The voltage at the second terminal 212 of the second voltage control circuitry 208 is a sense voltage Vsns. The gain control circuitry 214 operates to: receive Vsns at the first terminal 216; receive CLK at the second terminal 218; and provide CSR at the third terminal 219 responsive to Vsns and CLK. In some examples, the gain applied by the gain control circuitry 214 amplifies Vsns so that CSR has a target range (e.g., 0 to 5V, or 0 to 10V). The gain control circuitry 214 may also apply a gain that accounts for offsets introduced by the first voltage control circuitry 202 and/or the second voltage control circuitry 208.

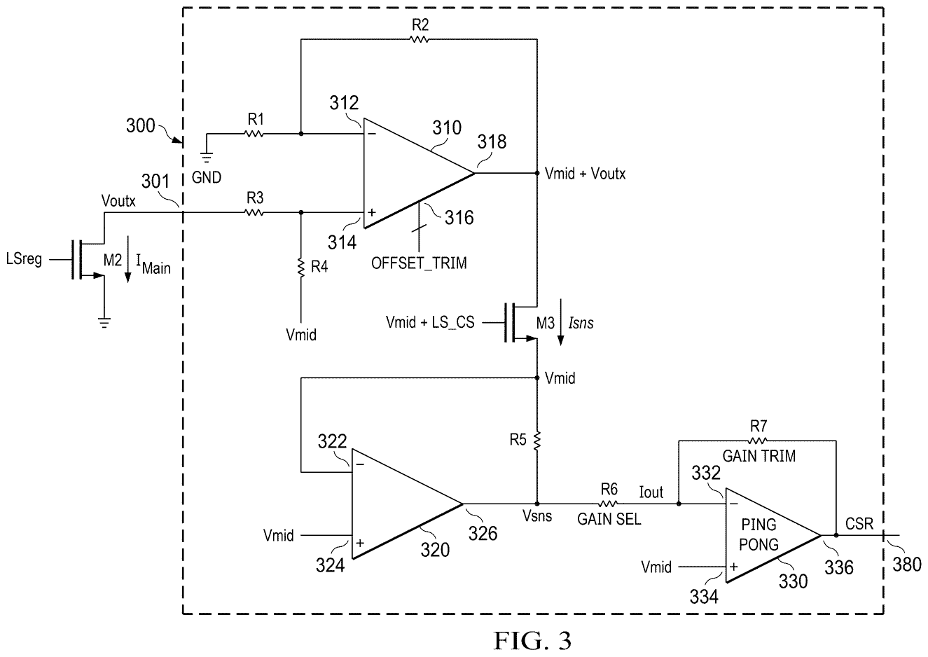

FIG. 3 is a diagram showing other example current sense circuitry 300 and the transistor M2. The current sense circuitry 300 is an example of the current sense circuitry 124 in FIG. 1 and the current sense circuitry 200 in FIG. 2. The current sense circuitry 300 has a first terminal 301 and a second terminal 380. The first terminal 301 of the current sense circuitry 300 is an example of the first terminal 126 of the current sense circuitry 124 in FIG. 1 or the first terminal 201 of the current sense circuitry 200 in FIG. 2. The second terminal 380 of the current sense circuitry 300 is an example of the third terminal 130 of the current sense circuitry 124 in FIG. 1 or the second terminal 230 of the current sense circuitry 200 in FIG. 2.

In the example of FIG. 3, current sense circuitry 300 includes resistors R1 to R7, the transistor M3, a first amplifier 310, a second amplifier 320, and a ping-pong amplifier 330 in the arrangement shown. As used herein, a “ping-pong amplifier” refers to a continuous-time auto-zeroing (CTAZ) amplifier or two matching (identical) amplifiers that operate to reduce offset voltage and noise. During operations, the matching amplifiers run out of phase with each other. As one matching amplifier captures its own error, the other matching produces a valid output. The matching amplifiers are controlled by a two-phase clock and operate in a “chop and average” sequence.

In the example of FIG. 3, each of the resistors R1 to R7 has a first terminal and a second terminal. The first amplifier 310 has a first terminal 312, a second terminal 314, a third terminal 316, and a fourth terminal 318. The second amplifier 320 has a first terminal 322, a second terminal 324, and a third terminal 326. The ping-pong amplifier 330 has a first terminal 332, a second terminal 334, and a third terminal 336. In the example of FIG. 3, the first terminal 312 of the first amplifier 310, the first terminal 322 of the second amplifier 320, and the first terminal 332 of the ping-pong amplifier 330 are inverting (“−”) terminals. The second terminal 314 of the first amplifier 310, the second terminal 324 of the second amplifier 320, and the second terminal 334 of the ping-pong amplifier 330 are non-inverting (“+”) terminals.

The first terminal 301 of the current sense circuitry 300 is coupled to the first terminal of the transistor M2 and the first terminal of the resistor R3. The second terminal of the resistor R3 is coupled to the first terminal of the resistor R4 and the second terminal 314 of the first amplifier 310. The second terminal of the resistor R4 is coupled to a Vmid source (not shown). The first terminal of the resistor R1 is coupled to ground or a ground terminal. The second terminal of the resistor R1 is coupled to the first terminal 312 of the first amplifier 310 and the first terminal of the resistor R2. The second terminal of the resistor R2 is coupled to the fourth terminal 318 of the first amplifier 310 and the first terminal of the transistor M3. The third terminal 316 of the first amplifier 310 is coupled to an OFFSET_TRIM source (e.g., the control circuitry 220 of FIG. 2). The second terminal of the transistor M3 is coupled to the first terminal of the resistor R5 and the first terminal 322 of the second amplifier 320. The second terminal 324 of the second amplifier 320 is coupled to a Vmid source (not shown). The third terminal 326 of the second amplifier 320 is coupled to the second terminal of the resistor R5 and the first terminal of the resistor R6. The second terminal of the resistor R6 is coupled to the first terminal of the resistor R7 and the first terminal 332 of the ping-pong amplifier 330. The second terminal 334 of the ping-pong amplifier 330 is coupled to a Vmid source (not shown). The third terminal 336 of the ping-pong amplifier 330 is coupled to the second terminal of the resistor R7 and to the second terminal 380 of the current sense circuitry 300.

In the example of FIG. 3, the resistors R1 to R4 and the first amplifier 310 are example components of the first voltage control circuitry 202 in FIG. 2. The resistor R5 and the second amplifier 320 are example components of the second voltage control circuitry 208. The resistors R6 and R7, and the ping-pong amplifier 330 are example components of the gain control circuitry 214 in FIG. 2.

In the example of FIG. 3, Voutx at the first terminal of the transistor M2 is based on the operations of a control loop as in FIG. 1. The control terminal of the transistor M2 receives LS_CS. The first amplifier 310 operates to: receive a scaled version of Voutx (based on the ratio of R3/R4) at the second terminal 314; receive OFFSET_TRIM at the third terminal 316; and provide a voltage level Vmid+Voutx at the fourth terminal 318 responsive to Voutx, OFFSET_TRIM, and the ratio of R2/R1. The first terminal of the transistor M3 is set at Vmid+Voutx. The control terminal of the transistor M3 receives Vmid+LS_CS. The second terminal of the transistor M3 is set at Vmid based on the operations of the second amplifier and the resistor R5 value. In the example of FIG. 3, the second amplifier 320 operates to: receive Vmid at the second terminal 324; provide Vmid at the first terminal 322; and provide Vsns at the third terminal 326 responsive to Vmid and the resistor R5 value. The ping-pong amplifier 330 operates to: receive Vmid at the second terminal 334; and provide CSR at the third terminal 336 responsive to Vmid and the ratio of R7/R6. In the example of FIG. 3, the resistor R7 value sets a first gain value (GAIN TRIM) applied to Vsns, resulting in CSR. The resistor R6 value sets a second gain value (GAIN SEL) that accounts for offsets introduced by the first amplifier 310 and/or the second amplifier 320.

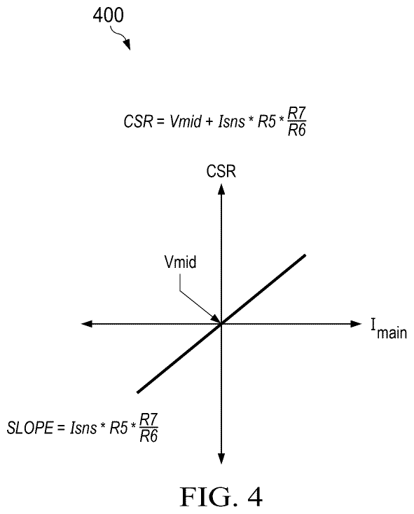

FIG. 4 is a graph 400 showing example current sense results. The graph 400 shows CSR as a function of Iₘₐᵢₙ (the current through the transistor M2). In the example of FIG. 4, CSR varies as a function of Iₘₐᵢₙ. When Iₘₐᵢₙ=0, CSR=Vmid. In some examples, CSR=Vmid+Isns*R5*R7/R6 and the slope of CSR (“SLOPE”)=Isns*R5*R7/R6, where Isns is the current through the transistor M3 in FIGS. 2 and 3. Centering CSR around Vmid instead of ground improves CSR accuracy when Iₘₐᵢₙ is near zero. This is because low Iₘₐᵢₙ current levels (e.g., below 5 mA) can cause low Isns and related dead zones in CSR.

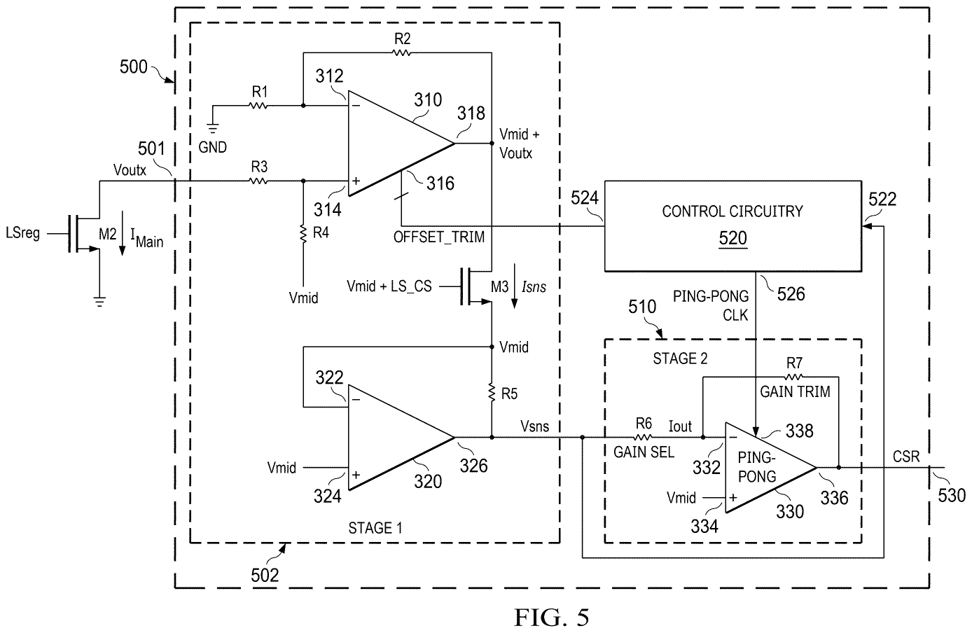

FIG. 5 is a diagram showing other example current sense circuitry 500 and the transistor M2. The current sense circuitry 500 is an example of the current sense circuitry 124 in FIG. 1 and the current sense circuitry 200 in FIG. 2. The current sense circuitry 500 has a first terminal 501 and a second terminal 530. The first terminal 501 of the current sense circuitry 500 is an example of the first terminal 126 of the current sense circuitry 124 in FIG. 1 or the first terminal 201 of the current sense circuitry 200 in FIG. 2. The second terminal 530 of the current sense circuitry 500 is an example of the third terminal 130 of the current sense circuitry 124 in FIG. 1 or the second terminal 230 of the current sense circuitry 200 in FIG. 2. In the example of FIG. 5, the current sense circuitry 500 includes the resistors R1 to R1, the transistor M3, the first amplifier 310, the second amplifier 320, and the ping-pong amplifier 330 with related terminals in the same arrangement as in FIG. 3.

In the example of FIG. 5, the resistors R1 to R5, the first amplifier 310, the transistor M3, and the second amplifier 320 are part of a first stage 502. The resistors R6 and R7, and the ping-pong amplifier 330 are part of a second stage 510. As shown, the ping-pong amplifier includes a fourth terminal 338 in FIG. 5, and the current sense circuitry 500 includes control circuitry 520. The control circuitry 520 has a first terminal 522, a second terminal 524, and a third terminal 526. In some examples, the control circuitry 520 includes analog-to-digital converters (ADCs) that operates to digitize Vsns and Vmid, first digital circuitry that operates to determine the difference between Vsns and Vmid, and second digital circuitry that operates to provide OFFSET_TRIM as a digital code responsive to the difference between Vsns and Vmid. A digital OFFSET_TRIM may be used to adjust one more trimmable resistors of the first voltage control circuitry 202 or the first amplifier 310 until Vsns is aligned with Vmid to within a threshold tolerance. In other examples, the control circuitry 520 includes first analog circuitry that operates to determine the difference between Vsns and Vmid, and second analog circuitry that generates OFFSET_TRIM as an analog control signal responsive to the difference between Vsns and Vmid. An analog OFFSET_TRIM may be used to adjust an input voltage input, reference voltage, or reference threshold of the first voltage control circuitry 202 or the first amplifier 310 until Vsns is aligned with Vmid to within a threshold tolerance.

In the example of FIG. 5, the first terminal 522 of the control circuitry 520 is coupled to the third terminal 326 of the second amplifier 320. The second terminal 524 of the control circuitry 520 is coupled to the third terminal 316 of the first amplifier 310. The third terminal 526 of the control circuitry 520 is coupled to the fourth terminal 338 of the ping-pong amplifier 330.

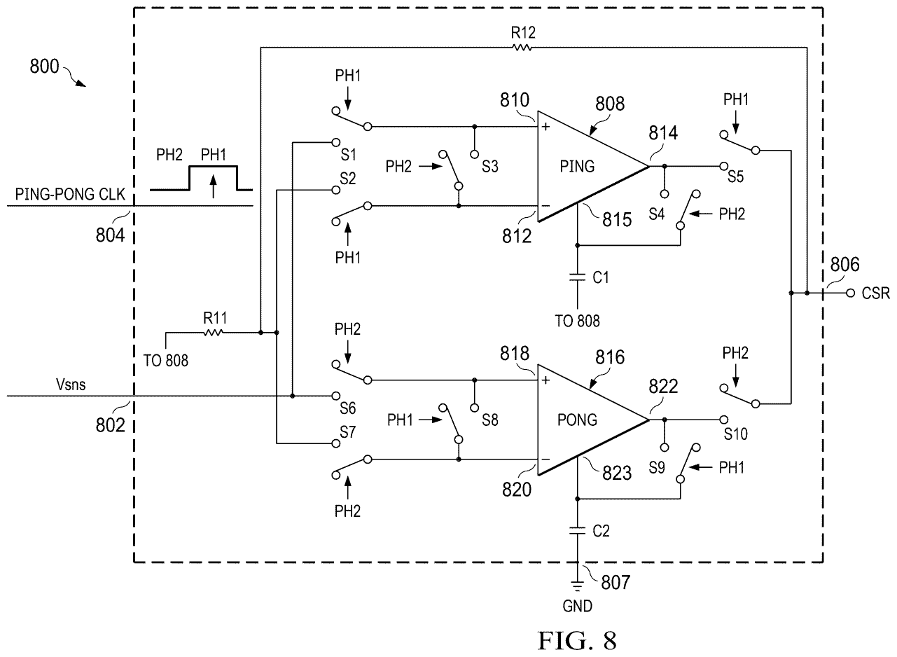

In the example of FIG. 5, the control circuitry 520 operates to: receive Vsns at the first terminal 522; provide OFFSET_TRIM at the second terminal 524 responsive to Vsns; and provide a ping-pong clock at the third terminal 526. The first stage 502 operates to:
receive Voutx; receive OFFSET_TRIM; and provide Vsns responsive to Voutx, OFFSET_TRIM, the operations of the first amplifier 310 and related resistor values (e.g., the values of resistors R1 to R4), the value of resistor R5, and the operations of the second amplifier 320. In the example of FIG. 5, Vsns is based on: Vmid+Voutx at the first terminal of the transistor M3; Vmid at the second terminal of the transistor M3; and Vmid+LS_CS at the control terminal of the transistor M3. The second stage 510 operates to: receive Vsns; receive PING-PONG CLK; and provide CSR responsive to Vsns, PING-PONG CLK, the value of resistors R6 and R7, and the operations of the ping-pong amplifier 330. An example ping-pong amplifier and related operations are described later (see FIG. 8 and related description).

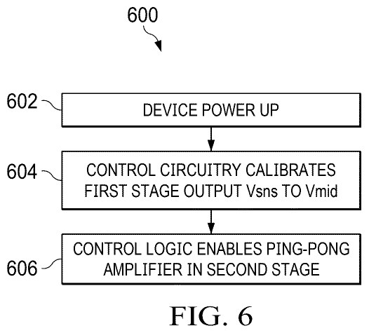

FIG. 6 is a flowchart showing an example current sense circuitry calibration method 600. The current sense circuitry calibration method 600 may be applied to the current sense circuitry 124 in FIG. 1, the current sense circuitry 200 in FIG. 2, the current sense circuitry 300 in FIG. 3, or the current sense circuitry 500 in FIG. 5. The current sense circuitry calibration method 600 includes device power up at block 602. At block 604, control circuitry (e.g., the control circuitry 520 in FIG. 5) calibrates the first stage output (Vsns) to Vmid. The first stage output refers to the output of the first stage 502 in FIG. 5. In some examples, the control circuitry calibrates Vsns to Vmid by adjusting OFFSET_TRIM until Vsns=Vmid to within a threshold. At block 606, control logic (e.g., the control circuitry 520 in FIG. 5) enables a ping-pong amplifier (e.g., the ping-pong amplifier 330 in FIGS. 3 to 5) in the second stage (e.g., the second stage 510 in FIG. 5). In some examples, the control circuitry starts providing PING-PONG CLK to the ping-pong amplifier after the calibration of block 604 is complete.

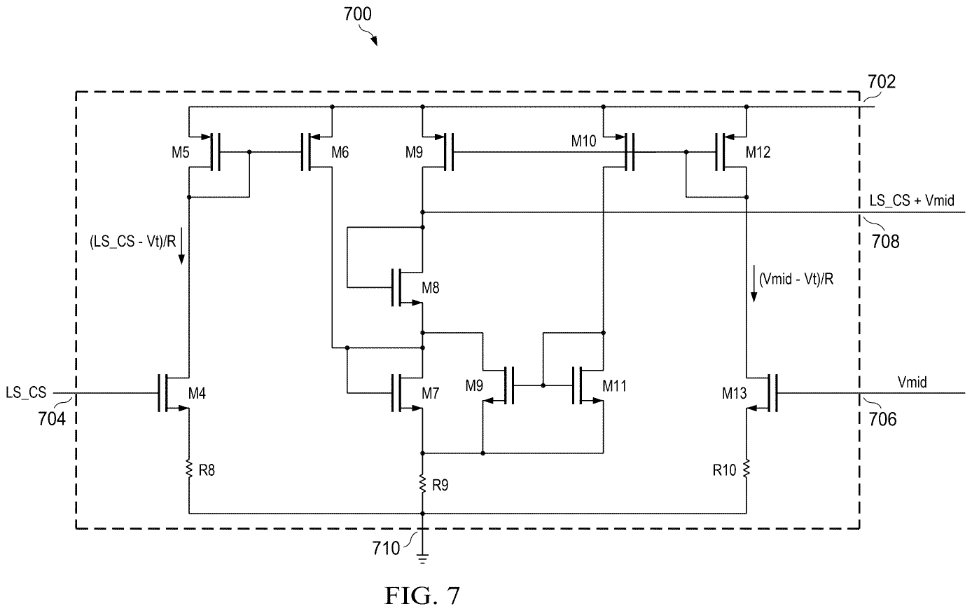

FIG. 7 is a schematic diagram showing example level-shift circuitry 700. In some examples, the level-shift circuitry 700 provides the voltage to the control terminal of the transistor M3 in FIGS. 2, 3, and 5. In such examples, the level-shift circuitry 700 may be added to the current sense circuitry 200 of FIG. 2, the current sense circuitry 300 of FIG. 3, or the current sense circuitry 500 in FIG. 5. In the example of FIG. 7, the level-shift circuitry 700 has a first terminal 702, a second terminal 704, a third terminal 706, a fourth terminal 708, and a fifth terminal 710. The level-shift circuitry 700 includes transistors M4 to M13 and resistors R8 to R10 in the arrangement shown. In the example of FIG. 7, each of the transistors M4 to M13 has a respective first terminal, a respective second terminal, and a respective control terminal. Each of the resistors R8 to R10 has a respective first terminal and a respective second terminal.

As shown, the first terminals of the transistors M5, M6, M9, M10, and M12 are coupled to the first terminal 702 of the level-shift circuitry 700. The second terminal of the transistor M5 is coupled to the first terminal of the transistor M4 and the control terminals of the transistors M5 and M6. The control terminal of the transistor M4 is coupled to the second terminal 704 of the level-shift circuitry 700. The second terminal of the transistor M4 is coupled to the first terminal of the resistor R8. The second terminal of the resistor R8 is coupled to the fourth terminal 708 of the level-shift circuitry 700. The second terminal of the transistor M6 is coupled to the second terminal of the transistor M6, the first terminal of the transistor M7, the control terminal of the transistor M7, and the first terminal of the transistor M9. The first terminal and the control terminal of the transistor M8 are coupled to the second terminal of the transistor M9 and the fourth terminal 708 of the level-shift circuitry 700. The second terminal of the transistor M10 is coupled to the first terminal of the transistors M11 and the control terminal of the transistors M9 and M11. The second terminal of the transistors M7, M9, and M11 are coupled to the first terminal of the resistor R9. The second terminal of the resistor R9 is coupled to the fifth terminal 710 of the level-shift circuitry 700. The second terminal of the transistor M12 is coupled to the first terminal of the transistor M13 and the control terminals of the transistors M9, M10, and M12. The second terminal of the transistor M13 is coupled to the first terminal of the resistor R10. The second terminal of the resistor R10 is coupled to the fifth terminal 710 of the level-shift circuitry 700. The control terminal of the transistor M13 is coupled to the third terminal 706 of the level-shift circuitry 700. In some examples, the transistor M4, M7, M8, and M13 are matched transistors with the same threshold voltage.

The level-shift circuitry 700 operates to: receive a power supply voltage at the first terminal 702; receive LS_CS at the second terminal 704; receive Vmid at the third terminal 706; and level shift LS_CS by Vmid to provide LS_CS+Vmid at the fourth terminal 708. In some examples, LS_CS has an on-state of 5V and Vmid is 1.4V. In such examples, LS_CS+Vmid is 6.4V to turn on the transistor M3 with an offset up to +/−58 mV. In other examples, LS_CS has an on-state of 5V and Vmid is 2.75V. In such examples, LS_CS+Vmid is 7.754V to turn on the transistor M3 with an offset up to +/−64 mV.

FIG. 8 is a diagram showing example gain control circuitry 800. The gain control circuitry 800 is an example of the gain control circuitry 214 in FIG. 2, the ping-pong amplifier 330 in FIG. 3, or the second stage 510 in FIG. 5. In the example of FIG. 8, the gain control circuitry 800 has a first terminal 802, a second terminal 804, a third terminal 806, and a fourth terminal 807. The gain control circuitry 800 includes resistors R11 and R12, switches S1 to S8, a ping amplifier 808, a pong amplifier 816, a capacitor C1, and a capacitor C2 in the arrangement shown. Each of the resistors R11 and R12 has a respective first terminal and a respective second terminal. With the gain control circuitry 800, the resistor R11 is an example of the resistor R6 in FIGS. 3 and 5. The resistor R12 is an example of the resistor R7 in FIGS. 3 and 3. Each of the switches S1 to S8 has a first terminal, a second terminal, and a control terminal. The ping amplifier 808 has a first terminal 810, a second terminal 812, a third terminal 814, and a fourth terminal 815. In some examples, the first terminal 810 of the ping amplifier 808 is a non-inverting (“+”) terminal. The second terminal 812 of the ping amplifier 808 is an inverting (“−”) terminal. The pong amplifier 816 has a first terminal 818, a second terminal 820, a third terminal 822, and a fourth terminal 823. In some examples, the first terminal 818 of the pong amplifier 816 is a non-inverting (“+”) terminal. The second terminal 820 of the pong amplifier 816 is an inverting (“−”) terminal. Each of the capacitors C1 and C2 has a respective first terminal and a second terminal.

The first terminal 802 of the gain control circuitry 800 is coupled to the first terminals of the switches S1 and S6. The second terminal of the switch S1 is coupled to the first terminal 810 of the ping amplifier 808 and the first terminal of the switch S3. The second terminal of the switch S3 is coupled to the second terminal 812 of the ping amplifier 808 and the second terminal of the switch S2. The first terminal of the switch S2 is coupled to the first terminal of the resistor R11, the first terminal of the resistor R12, and the first terminal of the switch S7. The second terminal of the resistor R11 is coupled to the fourth terminal 807. The second terminal of the switch S6 is coupled to the first terminal 818 of the pong amplifier 816 and the first terminal of the switch S8. The second terminal of the switch S8 is coupled to the second terminal 820 of the pong amplifier 816 and the second terminal of the switch S7.

The third terminal 814 of the ping amplifier 808 is coupled to the first terminals of the switches S4 and S5. The second terminal of the switch S5 is coupled to the second terminal of the resistor R12, the second terminal of the switch S10, and the third terminal of the gain control circuitry 800. The fourth terminal 815 of the ping amplifier 808 is coupled to the first terminal of the capacitor C1 and the second terminal of the switch S4. The second terminal of the capacitor C1 is coupled to the fourth terminal 807 of the gain control circuitry 800.

The third terminal 822 of the pong amplifier 816 is coupled to the first terminals of the switches S9 and S10. The fourth terminal 823 of the pong amplifier 816 is coupled to the first terminal of the capacitor C2 and the second terminal of the switch S9. The second terminal of the capacitor C2 is coupled to the fourth terminal 807 of the gain control circuitry 800. The control terminals of the switches S1 to S10 are coupled to the second terminal 804 of the gain control circuitry 800, which operates to: receive Vsns at the first terminal 802, receive PING-PONG CLK at the second terminal 804; and provide CSR at the third terminal 806 responsive to Vsns, the operation of the switches S1 to S10 based on PING-PONG CLK, the operations of the ping amplifier 808, and the operations of the pong amplifier 816. In the example of FIG. 8, PING-PONG CLK asserted (a logical “1”) is referred to as a first phase (PH1), and PING-PONG CLK de-asserted (a logical “0”) is referred to as a second phase (PH2). During the first phase, the switches S1, S2, and S5 are closed, and the ping amplifier 808 is active. Also, during the first phase, the switches S8 and S9 are closed, and the pong amplifier 816 performs offset cancellation. During the second phase, the switches S6, S7, and S10 are closed, and the pong amplifier 816 is active. Also, during the second phase, the switches S3 and S4 are closed, and ping amplifier 808 cancels its offset.

In some examples, the gain control circuitry 800 includes a ping-pong autozero operational amplifier with two identical amplifiers, a switch network for each amplifier, and sample-and-hold circuit for each amplifier. The ping-pong autozero operational amplifier is controlled by a two-phase clock (e.g., a 50 KHz clock). While one amplifier is processing signals, the other amplifier performs offset cancellation.

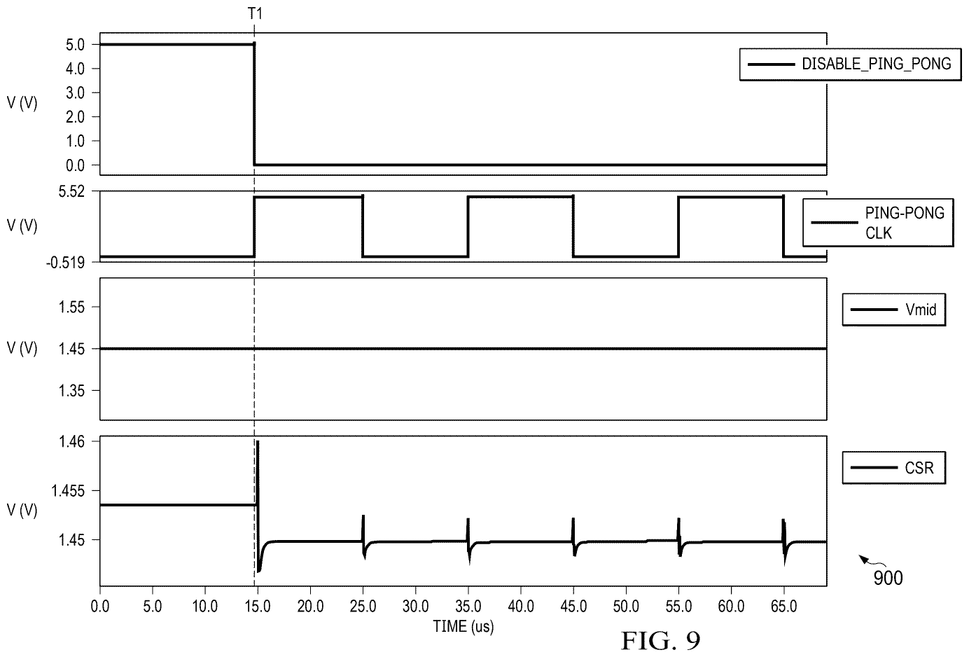

FIG. 9 is a timing diagram 900 showing example gain control circuitry signals. In the example of FIG. 9, the gain control circuitry signals include a disable ping-pong signal (DISABLE_PING-PONG), PING-PONG CLK, Vmid, and CSR. In FIG. 9, when DISABLE_PING-PONG is de-asserted, PING-PONG CLK is provided at a target rate (e.g., 50 kHz). Vmid stays constant (e.g., at 1.45V), resulting in a CSR that approximates Vmid (within 140 uV from Vmid).

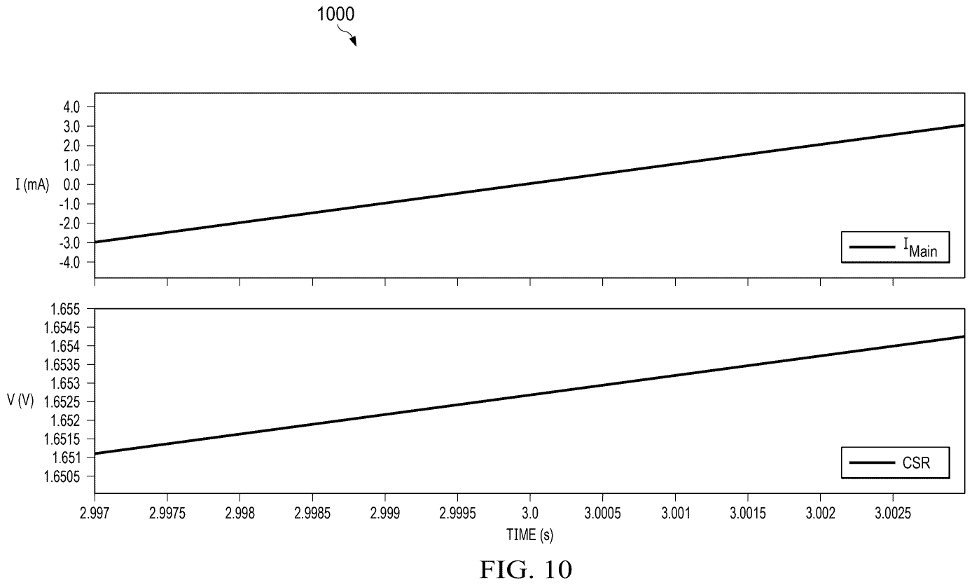

FIG. 10 is a graph 1000 showing example current and current sense results. In FIG. 10, I_{MAIN} ranges from −3A to 3A. In response, CSR ranges from 1.651V to 1.6545V. In different examples, the I_{MAIN} range and the related CSR range may vary.

In some examples, current sense circuitry (e.g., the current sense circuitry 124 in FIG. 1, the current sense circuitry 200 in FIG. 2, the current sense circuitry 300 in FIG. 3, the current sense circuitry 500 in FIG. 5) includes: a first amplifier (e.g., part of the first voltage control circuitry 202 in FIG. 2, or the first amplifier 310 in FIGS. 3 and 5); a transistor (e.g., the transistor M3 in FIGS. 2, 3, and 5); and a second amplifier (e.g., part of the second voltage control circuitry 208 in FIG. 2, or the second amplifier 320 in FIGS. 3 and 5). The first amplifier (e.g., the first amplifier 310 in FIGS. 3 and 5) has a first terminal (e.g., the first terminal 312 in FIGS. 3 and 5), a second terminal (e.g., the second terminal 314 in FIGS. 3 and 5), and a third terminal (e.g., the fourth terminal 318 in FIGS. 3 and 5). The transistor (e.g., the transistor M3 in FIGS. 3 and 5) has a first terminal (e.g., the drain terminal of the transistor M3), a second terminal (e.g., the source terminal of the transistor M3), and a control terminal (e.g., the gate terminal of the transistor M3). The first terminal (e.g., the drain terminal) of the transistor (e.g., the transistor M3) is coupled to the third terminal (e.g., the fourth terminal 318 in FIGS. 3 and 5) of the first amplifier (e.g., the first amplifier 310 in FIGS. 3 and 5)

The second amplifier (e.g., the second amplifier 320 in FIGS. 3 and 5) has a first terminal (e.g., the first terminal 322 in FIGS. 3 and 5), a second terminal (e.g., the second terminal 324 in FIGS. 3 and 5), and a third terminal (e.g., the third terminal 326 in FIGS. 3 and 5). The first terminal (e.g., the first terminal 322 in FIGS. 3 and 5) of the second amplifier (e.g., the second amplifier 320 in FIGS. 3 and 5) is coupled to the second terminal (e.g., the source terminal) of the transistor (e.g., the transistor M3 in FIGS. 3 and 4). In some examples, the current sense circuity includes: a first resistor (e.g., the resistor R1 in FIGS. 3 and 5); a second resistor (e.g., the resistor R2 in FIGS. 3 and 5); a third resistor (e.g., the resistor R3 in FIGS. 3 and 5); and a fourth resistor (e.g., the resistor R4 in FIGS. 3 and 5). The first resistor (e.g., R1 in FIGS. 3 and 5) has a first terminal (e.g., the right-side terminal of R1) and a second terminal (e.g., the left-side terminal of R1). The first terminal (e.g., the right-side terminal) of the first resistor is coupled to the first terminal (e.g., the first terminal 312 in FIGS. 3 and 5) of the first amplifier (e.g., the first amplifier 310 in FIGS. 3 and 5). The second resistor (e.g., R2 in FIGS. 3 and 5) has a first terminal (e.g., the left-side terminal of R2) and a second terminal (e.g., the right-side terminal of R2). The first terminal of the second resistor is coupled to the first terminal of the first amplifier. The second terminal of the second resistor is coupled to the third terminal of the first amplifier. The third resistor (e.g., R3 in FIGS. 3 and 5) has a first terminal (e.g., the left-side terminal of R3) and a second terminal (e.g., the right-side terminal of R3). The second terminal of the third resistor is coupled to the second terminal (e.g., the second terminal 314 in FIGS. 3 and 5) of the first amplifier. The fourth resistor (e.g., R4 in FIGS. 3 and 5) has a first terminal (e.g., the top-side terminal of R4) and a second terminal (e.g., the bottom-side terminal of R4). The first terminal of the fourth resistor coupled to the second terminal of the first amplifier. In some examples, the current sense circuitry includes a fifth resistor (e.g., R5 in FIGS. 3 and 5) having a first terminal (e.g., the top-side terminal of R5) and a second terminal (e.g., the bottom-side terminal of R5). The first terminal (e.g., the top-side terminal of R5) of the fifth resistor is coupled to the first terminal (e.g., the first terminal 322 in FIGS. 3 and 5) of the second amplifier (e.g., the second amplifier 320 in FIGS. 3 and 5). The second terminal (e.g., the bottom-side terminal of R5) of the fifth resistor is coupled to the third terminal (e.g., the third terminal 326 in FIGS. 3 and 5) of the second amplifier.

In some examples, the current sense circuitry includes a third amplifier (e.g., the ping-pong amplifier 330 in FIGS. 3 and 5) having a first terminal (e.g., the first terminal 332 in FIGS. 3 and 5), a second terminal (e.g., the second terminal 334 in FIGS. 3 and 5), and a third terminal (e.g., the third terminal 336 in FIGS. 3 and 5). The first terminal (e.g., first terminal 332 in FIGS. 3 and 5) of the third amplifier is coupled to the third terminal (e.g., the third terminal 326 in FIGS. 3 and 5) of the second amplifier. In some examples, the current sense circuitry includes a sixth resistor (e.g., R6 in FIGS. 3 and 5) and a seventh resistor (e.g., R7 in FIGS. 3 and 5). The sixth resistor has a first terminal (e.g., left-side terminal of R6) and a second terminal (e.g., the right-side terminal of R6). The first terminal (e.g., the left-side terminal of R6) of the sixth resistor is coupled to the third terminal (e.g., the third terminal 326 in FIGS. 3 and 5) of the second amplifier. The second terminal (e.g., the right-side terminal of R6) of the sixth resistor is coupled to the first terminal (e.g., the first terminal 332 in FIGS. 3 and 5) of the third amplifier. The seventh resistor (e.g., R7 in FIGS. 3 and 5) has a first terminal (e.g., the left-side terminal of R7) and a second terminal (e.g., the right-side terminal of R7). The first terminal of the seventh resistor is coupled to the first terminal of the third amplifier. The second terminal of the seventh resistor is coupled to the third terminal of the third amplifier.

In some examples, the first amplifier (e.g., the first amplifier 310 in FIGS. 3 and 5) has a fourth terminal (e.g., the third terminal 316 in FIGS. 3 and 5) and the third amplifier (e.g., the ping-pong amplifier 330 in FIGS. 3 and 5) has a fourth terminal (e.g., the fourth terminals 338 in FIGS. 3 and 5). In such examples, the current sense circuitry includes control circuitry (e.g., the control circuitry 520 in FIG. 5) having a first terminal (e.g., the first terminal 522 in FIG. 5), a second terminal (e.g., the second terminal 524 in FIG. 5), and a third terminal (e.g., the third terminal 526 in FIG. 5). The first terminal (e.g., the first terminal 522 in FIG. 5) of the control circuitry is coupled to the third terminal (e.g., the third terminal 326 in FIG. 5) of the second amplifier (e.g., the second amplifier 320 in FIG. 5). The second terminal (e.g., the second terminal 524 in FIG. 5) of the control circuitry is coupled to the fourth terminal (e.g., the third terminal 316 in FIGS. 3 and 5) of the first amplifier (e.g., the first amplifier 310). The third terminal (e.g., the third terminal 526 in FIG. 5) of the control circuitry is coupled to the fourth terminal (e.g., the fourth terminal 338 in FIG. 5) of the third amplifier.

In some examples, a circuit includes: a first transistor (e.g., the transistor M2 in FIGS. 3 and 5); a first amplifier (e.g., the first amplifier 310 in FIGS. 3 and 5); a first resistor (e.g., R1 in FIGS. 3 and 5); a second resistor (e.g., R2 in FIGS. 3 and 5); a third resistor (e.g., R3 in FIGS. 3 and 5); a fourth resistor (e.g., R4 in FIGS. 3 and 5); a second transistor (e.g., the transistor M3 in FIGS. 3 and 5); and a second amplifier (e.g., the second amplifier 320 in FIGS. 3 and 5). The first transistor has a first terminal, a second terminal, and a control terminal. The first amplifier has a first terminal, a second terminal, and a third terminal. The first terminal of the first amplifier is coupled to the first terminal of the first transistor. The first resistor has a first terminal and a second terminal. The first terminal of the first resistor is coupled to the first terminal of the first amplifier. The second resistor has a first terminal and a second terminal. The first terminal of the second resistor is coupled to the first terminal of the first amplifier. The second terminal of the second resistor is coupled to the third terminal of the first amplifier. The third resistor has a first terminal and a second terminal. The second terminal of the third resistor is coupled to the second terminal of the first amplifier. The fourth resistor has a first terminal and a second terminal. The first terminal of the fourth resistor is coupled to the second terminal of the first amplifier. The second transistor has a first terminal, a second terminal, and a control terminal. The first terminal of the second transistor is coupled to the third terminal of the first amplifier. The second amplifier has a first terminal, a second terminal, and a third terminal. The first terminal of the second amplifier is coupled to the second terminal of the second transistor.

In some examples, the circuit includes a fifth resistor having a first terminal and a second terminal. The first terminal of the fifth resistor is coupled to the first terminal of the second amplifier. The second terminal of the fifth resistor is coupled to the third terminal of the second amplifier. In some examples, the circuit includes amplifier circuitry having a first terminal, a second terminal, and a third terminal. The first terminal of the amplifier circuitry is coupled to the third terminal of the second amplifier.

In some examples, the circuit includes: a sixth resistor and a seventh resistor. The sixth resistor has a first terminal and a second terminal. The first terminal of the sixth resistor coupled to the third terminal of the second amplifier. The second terminal of the sixth resistor coupled to the first terminal of the amplifier circuitry. The seventh resistor has a first terminal and a second terminal. The first terminal of the seventh resistor is coupled to the first terminal of the amplifier circuitry. The second terminal of the seventh resistor is coupled to the third terminal of the amplifier circuitry.

In some examples, the first amplifier has a fourth terminal and the amplifier circuitry has a fourth terminal. In such examples, the circuit includes control circuitry having a first terminal, a second terminal, and a third terminal. The first terminal of the control circuitry is coupled to the third terminal of the second amplifier. The second terminal of the control circuitry is coupled to the fourth terminal of the first amplifier. The third terminal of the control circuitry is coupled to the fourth terminal of the amplifier circuitry. In some examples, the circuit includes level-shift circuitry (e.g., the level-shift circuitry 700 in FIG. 7) having a first terminal (e.g., the second terminal 704 in FIG. 7), a second terminal (e.g., the third terminal 706 in FIG. 7), and a third terminal (e.g., the fourth terminal 708 in FIG. 7). The first terminal (e.g., the second terminal 704 in FIG. 7) of the level-shift circuitry is coupled to the control terminal of the first transistor (e.g., the transistor M2 in FIGS. 3 and 5). The second terminal (e.g., the third terminal 706 in FIG. 7) of the level-shift circuitry is coupled to the first terminal (e.g., the first terminal 322 in FIGS. 3 and 5) of the second amplifier (e.g., the second amplifier 320 in FIGS. 3 and 5). The third terminal (e.g., the fourth terminal 708 in FIG. 7) of the level-shift circuitry is coupled to the control terminal of the second transistor (e.g., the transistor M3 in FIGS. 3 and 5).

In some examples, the amplifier circuitry (e.g., the ping-pong amplifier 330 in FIGS. 3 and 5) includes: a third amplifier (e.g., the ping amplifier 808 in FIG. 8); a first switch network (e.g., switches S1 to S5 in FIG. 8) for the third amplifier; a fourth amplifier (e.g., the pong amplifier 816 in FIG. 8); and a second switch network (e.g., switches S6 to S10 in FIG. 8) for the fourth amplifier. The first and second switch networks are configured to: receive clock signals (e.g., PH1 and PH2 in FIG. 8) with different phases; enable sampling by the third amplifier and the fourth amplifier during different non-overlapping intervals; and enable offset correction by the third amplifier and the fourth amplifier during different non-overlapping intervals.

In some examples, a circuit includes a transistor (e.g., the transistor M3 in FIGS. 3 and 5) having a first terminal (e.g., drain terminal of M3), a second terminal (e.g., the source terminal of M3), and a control terminal (e.g., the gate terminal of M3). The circuit also includes: first amplifier circuitry (e.g., the first voltage control circuitry 202 in FIG. 2, or the first amplifier 310 in FIGS. 3 and 5); second circuitry (e.g., the second voltage control circuitry 208 in FIG. 2, or the second amplifier 320 in FIGS. 3 and 5); third amplifier circuitry (e.g., the ping-pong amplifier 330 in FIGS. 3 and 5); and control circuitry (e.g., the control circuitry 220 in FIG. 2, or the control circuitry 520 in FIG. 5).

The first amplifier circuitry has a first terminal (e.g., the first terminal 312 in FIGS. 3 and 5), a second terminal (e.g., the second terminal 314 in FIGS. 3 and 5), and a third terminal (e.g., the fourth terminal 318 in FIGS. 3 and 5). The third terminal (e.g., the fourth terminal 318 in FIGS. 3 and 5) of the first amplifier circuitry is coupled to the first terminal of the transistor. The second amplifier circuitry has a first terminal (e.g., the first terminal 322 in FIGS. 3 and 5), a second terminal (e.g., the second terminal 324 in FIGS. 3 and 5), and a third terminal (e.g., the third terminal 326 in FIGS. 3 and 5). The first terminal of the second amplifier circuitry is coupled to the second terminal of the transistor. The third amplifier circuitry has a first terminal (e.g., the first terminal 332 in FIGS. 3 and 5), a second terminal (e.g., the second terminal 334 in FIGS. 3 and 5), a third terminal (e.g., the third terminal 336 in FIGS. 3 and 5), and a fourth terminal (e.g., the fourth terminal 338 in FIGS. 3 and 5). The first terminal (e.g., the first terminal 332 in FIGS. 3 and 5) of the third amplifier circuitry is coupled to the third terminal (e.g., the third terminal 326 in FIGS. 3 and 5) of the second amplifier circuitry. The control circuitry has a terminal (e.g., the third terminal 526 in FIG. 5) coupled to the fourth terminal (e.g., the fourth terminal 338 in FIGS. 3 and 5) of the third amplifier circuitry.

In some examples, the terminal of the control circuitry is a first terminal, the first amplifier circuitry has a fourth terminal (e.g., the third terminal 316 in FIGS. 3 and 5), the control circuitry has a second terminal (e.g., the second terminal 524 in FIG. 5), and the second terminal of the control circuitry is coupled to the fourth terminal of the first amplifier circuitry. In some examples, the third amplifier circuitry (e.g., the ping-pong amplifier 330 in FIGS. 3 and 5) includes: a first amplifier (e.g., the ping amplifier 808 in FIG. 8); a first switch network for the first amplifier (e.g., switches S1 to S5 in FIG. 8); a second amplifier (e.g., the pong amplifier 823 in FIG. 8); and a second switch network (e.g., switches S6 to S10 in FIG. 8) for the second amplifier.

In some examples, the circuit further comprises level-shift circuitry (e.g., the level-shift circuitry 700 in FIG. 7) having a first terminal (e.g., the first terminal 704 in FIG. 7), a second terminal (e.g., second terminal 706 in FIG. 7), and a third terminal (e.g., the third terminal 708 in FIG. 7). The third terminal of the level-shift circuitry is coupled to the control terminal of the transistor. In such examples, the first amplifier circuitry is configured to: receive a first voltage (e.g., Vmid); and set a voltage at the first terminal of the transistor to the first voltage plus a second voltage (Vmid+Voutx). The second amplifier circuitry is configured to set a voltage at the second terminal of the transistor to the second voltage (e.g., Vmid). The level-shift circuitry is configured to receive a switch control voltage (e.g., LS_CS) at the first terminal (e.g., the first terminal 704 in FIG. 7); receive the second voltage (e.g., Vmid) at the second terminal (e.g., the second terminal 706 in FIG. 7) of the level-shift circuitry; and provide the second voltage plus a switch control voltage (e.g., LS_CS+Vmid) at the third terminal (e.g., the third terminal 708 in FIG. 7) of the level-shift circuitry. In such examples, the first and second switch networks are configured to: receive clock signals (PH1 and PH2) with different phases; enable sampling by the first amplifier and the second amplifier during different non-overlapping intervals; and enable offset correction by the first amplifier and the second amplifier during different non-overlapping intervals.

In some examples, the third amplifier circuitry is configured to: receive a sense voltage (e.g., Vsns herein) at the first terminal (e.g., the first terminal 332 in FIGS. 3 and 5) of the third amplifier circuitry, the sense voltage based on the first voltage (e.g., Vmid), the second voltage (e.g., Voutx), and the switch control voltage (e.g., LS_CS); and provide an amplified sense voltage (CSR) at the third terminal of the third amplifier circuitry based on the sense voltage, a first gain setting (e.g., GAIN TRIM in FIGS. 3 and 5), and a second gain setting (e.g., GAIN SEL in FIGS. 3 and 5). In some examples, the first gain setting (e.g., GAIN TRIM) is based on a target voltage range for the amplified sense voltage (e.g., CSR), and the second gain setting (e.g., GAIN SEL) accounts for offsets introduced by the first circuitry (e.g., the first voltage control circuitry 202 in FIG. 2, or the first amplifier 310 in FIGS. 3 and 5) and the second circuitry (e.g., the second voltage control circuitry 208 in FIG. 2, or the second amplifier 320 in FIGS. 3 and 5).

In some examples, the transistor (e.g., the transistor M3 in FIGS. 3 and 5) is a first transistor, and the circuit includes a second transistor (e.g., the transistor M2 in FIGS. 2, 3, and 5) having a first terminal (e.g., the drain terminal of M2), a second terminal (e.g., the source terminal of M2), and a control terminal (e.g., the gate terminal of M2). In such examples, voltage at the control terminal of the second transistor is the switch control voltage (e.g., LS_CS in FIGS. 3 and 5), voltage at the first terminal of the second transistor is the first voltage (e.g., Voutx in FIGS. 3 and 5). In some examples, the circuit includes: an ADC (e.g., the ADC 132 in FIG. 1); a microcontroller (e.g., the microcontroller 102 in FIG. 1); and a PWM (e.g., the PWM 108 in FIG. 1). The ADC (e.g., the ADC 132) has a first terminal (e.g., the first terminal 134) and a second terminal (e.g., the second terminal 136). The first terminal of the ADC is coupled to the second terminal (e.g., the third terminal 336 in FIGS. 3 and 5) of the fourth circuitry (e.g., ping-pong amplifier 330 in FIGS. 3 and 5). The microcontroller has a first terminal (e.g., the first terminal 104 in FIG. 1) and a second terminal (e.g., the first terminal 104 in FIG. 1). The first terminal (e.g., the first terminal 104) of the microcontroller is coupled to the second terminal (e.g., the second terminal 136) of the ADC. The PWM has a first terminal (e.g., the first terminal 110 in FIG. 1) and a second terminal (e.g., the third terminal 114 in FIG. 1). The first terminal (e.g., the first terminal 110) of the PWM is coupled to the second terminal (e.g., the second terminal 106) of the microcontroller. The second terminal (e.g., the third terminal 114) of the PWM is coupled to the control terminal of the second transistor (e.g., the transistor M2 in FIGS. 2, 3, and 5).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. Current sense circuitry comprising:
a first amplifier having a first terminal, a second terminal, and a third terminal;
a transistor having a first terminal, a second terminal, and a control terminal, the first terminal of the transistor coupled to the third terminal of the first amplifier; and
a second amplifier having a first terminal, a second terminal, and a third terminal, the first terminal of the second amplifier coupled to the second terminal of the transistor.

2. The current sense circuitry of claim 1, further comprising:
a first resistor having a first terminal and a second terminal, the first terminal of the first resistor coupled to the first terminal of the first amplifier;
a second resistor having a first terminal and a second terminal, the first terminal of the second resistor coupled to the first terminal of the first amplifier, and the second terminal of the second resistor coupled to the third terminal of the first amplifier;
a third resistor having a first terminal and a second terminal, the second terminal of the third resistor coupled to the second terminal of the first amplifier; and
a fourth resistor having a first terminal and a second terminal, the first terminal of the fourth resistor coupled to the second terminal of the first amplifier.

3. The current sense circuitry of claim 2, further comprising a fifth resistor having a first terminal and a second terminal, the first terminal of the fifth resistor coupled to the first terminal of the second amplifier, and the second terminal of the fifth resistor coupled to the third terminal of the second amplifier.

4. The current sense circuitry of claim 3, further comprising a third amplifier having a first terminal, a second terminal, and a third terminal, the first terminal of the third amplifier coupled to the third terminal of the second amplifier.

5. The current sense circuitry of claim 4, further comprising:
a sixth resistor having a first terminal and a second terminal, the first terminal of the sixth resistor coupled to the third terminal of the second amplifier, and the second terminal of the sixth resistor coupled to the first terminal of the third amplifier; and
a seventh resistor having a first terminal and a second terminal, the first terminal of the seventh resistor coupled to the first terminal of the third amplifier, and the second terminal of the seventh resistor coupled to the third terminal of the third amplifier.

6. The current sense circuitry of claim 5, wherein the first amplifier has a fourth terminal, the third amplifier has a fourth terminal, the current sense circuitry further comprises control circuitry having a first terminal, a second terminal, and a third terminal, the first terminal of the control circuitry coupled to the third terminal of the second amplifier, the second terminal of the control circuitry coupled to the fourth terminal of the first amplifier, and the third terminal of the control circuitry coupled to the fourth terminal of the third amplifier.

7. A circuit comprising:
a first transistor having a first terminal, a second terminal, and a control terminal;
a first amplifier having a first terminal, a second terminal, and a third terminal, the first terminal of the first amplifier coupled to the first terminal of the first transistor;
a first resistor having a first terminal and a second terminal, the first terminal of the first resistor coupled to the first terminal of the first amplifier;
a second resistor having a first terminal and a second terminal, the first terminal of the second resistor coupled to the first terminal of the first amplifier, and the second terminal of the second resistor coupled to the third terminal of the first amplifier;
a third resistor having a first terminal and a second terminal, the second terminal of the third resistor coupled to the second terminal of the first amplifier;
a fourth resistor having a first terminal and a second terminal, the first terminal of the fourth resistor coupled to the second terminal of the first amplifier;
a second transistor having a first terminal, a second terminal, and a control terminal, the first terminal of the second transistor coupled to the third terminal of the first amplifier; and
a second amplifier having a first terminal, a second terminal, and a third terminal, the first terminal of the second amplifier coupled to the second terminal of the second transistor.

8. The circuit of claim 7, further comprising a fifth resistor having a first terminal and a second terminal, the first terminal of the fifth resistor coupled to the first terminal of the second amplifier, and the second terminal of the fifth resistor coupled to the third terminal of the second amplifier.

9. The circuit of claim 8, further comprising amplifier circuitry having a first terminal, a second terminal, and a third terminal, the first terminal of the amplifier circuitry coupled to the third terminal of the second amplifier.

10. The circuit of claim 9, further comprising:
a sixth resistor having a first terminal and a second terminal, the first terminal of the sixth resistor coupled to the third terminal of the second amplifier, and the second terminal of the sixth resistor coupled to the first terminal of the amplifier circuitry; and
a seventh resistor having a first terminal and a second terminal, the first terminal of the seventh resistor coupled to the first terminal of the amplifier circuitry, and the second terminal of the seventh resistor.

11. The circuit of claim 10, wherein the first amplifier has a fourth terminal, the amplifier circuitry has a fourth terminal, the circuit further comprises control circuitry having a first terminal, a second terminal, and a third terminal, the first terminal of the control circuitry coupled to the third terminal of the second amplifier, the second terminal of the control circuitry coupled to the fourth terminal of the first amplifier, and the third terminal of the control circuitry coupled to the fourth terminal of the amplifier circuitry.

12. The circuit of claim 9, further comprising level-shift circuitry having a first terminal, a second terminal, and a third terminal, the first terminal of the level-shift circuitry coupled to the control terminal of the first transistor, the second terminal of the level-shift circuitry coupled to the first terminal of the second amplifier, and the third terminal of the level-shift circuitry coupled to the control terminal of the second transistor.

13. The circuit of claim 9, wherein the amplifier circuitry includes:
a third amplifier;
a first switch network for the third amplifier;
a fourth amplifier; and
a second switch network for the fourth amplifier, the first and second switch networks configured to:
receive clock signals with different phases;
enable sampling by the third amplifier and the fourth amplifier during different non-overlapping intervals; and
enable offset correction by the third amplifier and the fourth amplifier during different non-overlapping intervals.

14. A circuit comprising:
a transistor having a first terminal, a second terminal, and a control terminal;
first amplifier circuitry having a first terminal, a second terminal, and a third terminal, the third terminal of the first amplifier circuitry coupled to the first terminal of the transistor;
second amplifier circuitry having a first terminal, a second terminal, and a third terminal, the first terminal of the second amplifier circuitry coupled to the second terminal of the transistor;
third amplifier circuitry having a first terminal, a second terminal, a third terminal, and a fourth terminal, the first terminal of the third amplifier circuitry coupled to the third terminal of the second amplifier circuitry; and
control circuitry having a terminal coupled to the fourth terminal of the third amplifier circuitry.

15. The circuit of claim 14, wherein the terminal of the control circuitry is a first terminal, the first amplifier circuitry has a fourth terminal, the control circuitry has a second terminal, and the second terminal of the control circuitry is coupled to the fourth terminal of the first amplifier circuitry.

16. The circuit of claim 14, wherein the third amplifier circuitry includes:
a first amplifier;
a first switch network coupled to the first amplifier;
a second amplifier; and
a second switch network coupled to the second amplifier.

17. The circuit of claim 16, further comprising level-shift circuitry having a first terminal, a second terminal, and a third terminal, the third terminal of the level-shift circuitry coupled to the control terminal of the transistor,
wherein the first amplifier circuitry is configured to:
receive a first voltage; and
set a voltage at the first terminal of the transistor to the first voltage plus a second voltage,
the second amplifier circuitry is configured to set a voltage at the second terminal of the transistor to the second voltage,
the level-shift circuitry is configured to:
receive a switch control voltage at the first terminal of the level-shift circuitry;
receive the second voltage at the second terminal of the level-shift circuitry; and
provide the second voltage plus the switch control voltage at the third terminal of the level-shift circuitry, and
the first and second switch networks are configured to:
receive clock signals with different phases;
enable sampling by the first amplifier and the second amplifier during different non-overlapping intervals; and
enable offset correction by the first amplifier and the second amplifier during different non-overlapping intervals.

18. The circuit of claim 17, wherein the third amplifier circuitry is configured to:
receive a sense voltage at the first terminal of the third amplifier circuitry, the sense voltage based on the first voltage, the second voltage, and the switch control voltage; and
provide an amplified sense voltage at the third terminal of the third amplifier circuitry based on the sense voltage, a first gain setting, and a second gain setting.

19. The circuit of claim 18, wherein the first gain setting is based on a target voltage range for the amplified sense voltage, and the second gain setting accounts for offsets introduced by the first circuitry and the second circuitry.

20. The circuit of claim 17, wherein the transistor is a first transistor, the circuit further comprises a second transistor having a first terminal, a second terminal, and a control terminal, voltage at the control terminal of the second transistor is the switch control voltage, voltage at the first terminal of the second transistor is the first voltage, and the circuit further comprises:
an analog-to-digital converter (ADC) having a first terminal and a second terminal, the first terminal of the ADC coupled to the second terminal of the fourth circuitry;
a microcontroller having a first terminal and a second terminal, the first terminal of the microcontroller coupled to the second terminal of the ADC; and
a pulse-width modulator (PWM) having a first terminal and a second terminal, the first terminal of the PWM coupled to the second terminal of the microcontroller, and the second terminal of the PWM coupled to the control terminal of the second transistor.
